(19) United States
(12) Patent Application Publication
(10) Pub. No.: US 2007/0057351 A1
(43) Pub. Date: Mar. 15, 2007

(54) Structure of IC packaging and method forming the same

(75) Inventors: Chih-Tai Hsu, Taipei (TW); Chung-Ju Wu, Kaohsiung City (TW)

Correspondence Address: BIRCH STEWART KOLASCH & BIRCH, PO BOX 747, FALLS CHURCH, VA, 22040-0747, US

(73) Assignee: SILICON INTEGRATED SYSTEMS CORP.

(21) Appl. No.: 11/449,744

(22) Filed: Jun. 9, 2006

(30) Foreign Application Priority Data
Sep. 14, 2005 (TW) 94131717

(51) Int. Cl. H01L 23/495; H01L 23/48

(52) U.S. Cl. 257/666; 257/782; 257/E23.06

(57) ABSTRACT

A structure of IC packaging and a method forming the same are disclosed in the present invention. This structure of IC packaging comprises a substrate, a chip, and a plurality of copper connecting wires. At least a conductive structure is made on the substrate and an isolating material is coated on the copper connecting wires. The chip is fastened on the substrate and electrically connected with the conductive structure by the copper conductive wires coated with isolating material.

### BACKGROUND OF THE INVENTION

1. Field of the Invention

The present invention generally relates to a packaging structure and method forming the same, and more particularly relates to a packaging structure with copper-conductive wires coated with isolating material and the method forming the same.

2. Description of the Prior Art

Wire bonding is one of integrated circuits packaging techniques for transmitting signals. The conductive wires, such as gold wire, are bonded from the pads of the die to the bonding fingers of the packaging substrate to transmit signals. Signals are transmitted from the pads of the die to the bonding fingers of the packaging substrate and further transmitted through the trace routing of the substrate, conductive vias, low layer circuits and finally to the solder balls at the bottom of the substrate.

FIG. 1 is a cross-section diagram illustrating a packaging structure. A die 102 is disposed on the packaging substrate 118 and the die 102 is connected with the bonding fingers 106 on the packaging substrate 118 through the gold wires 104. The bonding fingers 106 are connected to the trace routing 108 of the substrate 118, and the trace routing 108 is further connected to the solder ball 114 at the bottom of the substrate 118 by the conductive vias 110 and the low layer circuit 112. A complete circuit is formed by the connection and the signal is transferred to external circuit by this complete circuit. The die 102 is fastened on the substrate 118 by the silver-filled epoxy 116. An isolating material, such as molding compound 120, is formed around the gold wires 104 to prevent the shorting among the gold wires 104. The molding compound 120 is covered by a thermally conductive cover structure 122.

As the packaging structures get smaller and its circuitry more complex, the density of the bonding wires greatly increases. Because the number of the gold wires is so many and the intervals between the gold wires are so close, the gold wires are easily shorted in the packaging process. The length of the gold wires and the arrangement of the boding fingers are strictly controlled and limited to prevent the gold wires from being too close to each other and being crossing to each other to decrease the probability of shorting of the packaging structure. Furthermore, in order to reduce the electrical interrupt between the gold wires in the prior art, it is necessary to add shielding wires between adjacent gold wires. The number of the wire bonds of the packaging product is greatly increased in the packaging products. Therefore, the packaging process becomes too complicated because of great number of the wire bonds. The cost and the time of packaging is also increased greatly. In the conventional packaging structure, even the shielding wires are used to avoid the short of gold wires and reduce the cross talk of the gold wires. But the magnetic interrupt between the gold wires is hard to be avoided in the conventional packaging structure. Moreover, the material for forming the gold wires is expensive, the more gold wires are used in the packaging structure, the more cost of the packaging structure is.

For the mentioned reasons, a packaging structure and the method forming the same of the invention is disclosed.

### SUMMARY OF THE INVENTION

In view of the foregoing, one object of the present invention is to provide a packaging structure that can shield the electrical interrupt efficiently. Therefore the electrical interrupt and the short in prior art because of the closing and the crossing of the gold wires can be solved.

Another object of the present invention is to provide a packaging method that can shield the electrical interrupt without the electrical shielding wire bonding. Therefore, the problems of the prior art such as he high integration of the gold wires, the difficulty of wire boding and packaging, the complication of trace routing design and the increasing of the cost which are caused by adding the shielding wires between the gold wires, can be solved.

According to the object, one embodiment of the present invention provides a packaging structure and the method forming the same. The package structure comprises a substrate has a plurality of pads (such as fingers on the substrate). Each of the pads is electrical connected to the corresponding solder ball by the internal circuits and the signal is transmitted by this connection. After a die is mounted on the substrate, copper conductive wires covered by an isolating material are bonded. By the way, even the copper conductive wires touch each other or cross each other because of the high integration or density, there is no electrical interrupt or short to be occurred in the packaging structure of the present invention. Furthermore, in the present invention, the complex trace routing design is simplified and the short between the conductive wires is avoided.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional view illustrating a conventional packaging structure;

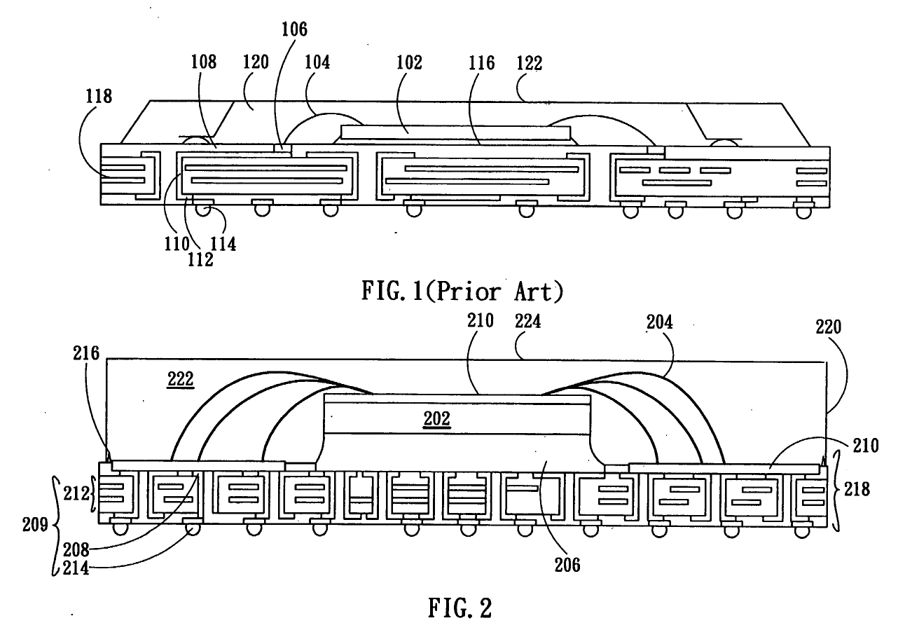

FIG. 2 is a cross-sectional view illustrating a packaging structure in accordance with one embodiment of the present invention;

FIG.3A to 3E illustrate the method of forming the packaging structure showed in FIG.2;

FIG. 4 is a cross-sectional view illustrating a packaging structure in which there is a electrical shielding in accordance with another embodiment of the present invention; and

FIG. 5A to 5B are cross-sectional diagrams illustrating the difference arrangement of the insulating layer in accordance with the other embodiment of the present invention.

### DESCRIPTION OF THE PREFERRED EMBODIMENT

The following is the detail description of the present invention. It should be noted and appreciated that the process steps and structures described below do not cover a complete process flow and structure. The present invention can be practiced in conjunction with various fabrication techniques that are used in the art, and only so much of the commonly practiced process steps are included herein as are necessary to provide an understanding of the present invention.

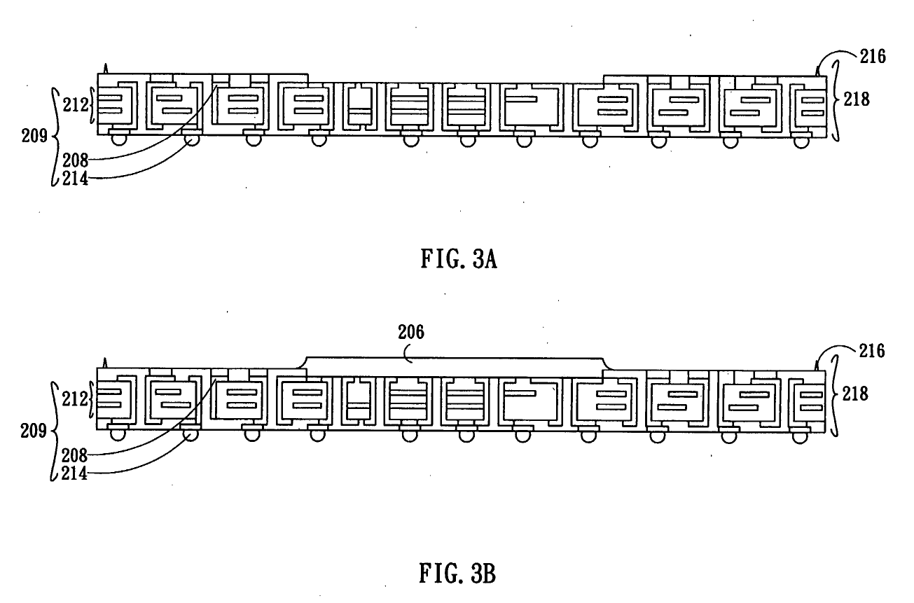

FIG. 2 is a cross-section view illustrating a packaging structure in accordance with one embodiment of the present invention. The packaging structure comprises a substrate 218 and the substrate 218 has a conductive structure 209. The conductive structure comprises a first conductive structure 208 and a second conductive structure 214. The first conductive structure 208 is formed on one side of the substrate 218, which can be pads (such as bonding fingers), or other shapes of the conductive structures (such as block shape or circle shape). The second conductive structure 214 is formed on the other side of the substrate 218, which can be solder balls or any shapes of material with conductivity. In addition, the inner circuits 212 of the substrate 218, such as conductive vias or metal pattern layers, is used to connect the first conductive structure 208 with the corresponding second conductive structure 214.

A die 202 (or chip) is fastened on the substrate 218 and there are many methods to fasten the die 202. In the embodiment of the present invention, the die 202 is fasten (or attached) on the substrate 218 by using a die-attach material 206 such as soldering, or other fastening techniques to be adapted. In the other embodiment, the die 202 is directly fastened on the substrate 218 without attaching material. In this embodiment of the present invention, the die-attach material 206 is an electrically conductive adhesive material, such as solders or silver-filled epoxy. But in the other embodiment of the present invention, the die-attach material 206 can be an electrically insulating adhesive material, such as epoxy resin polyimide and etc.

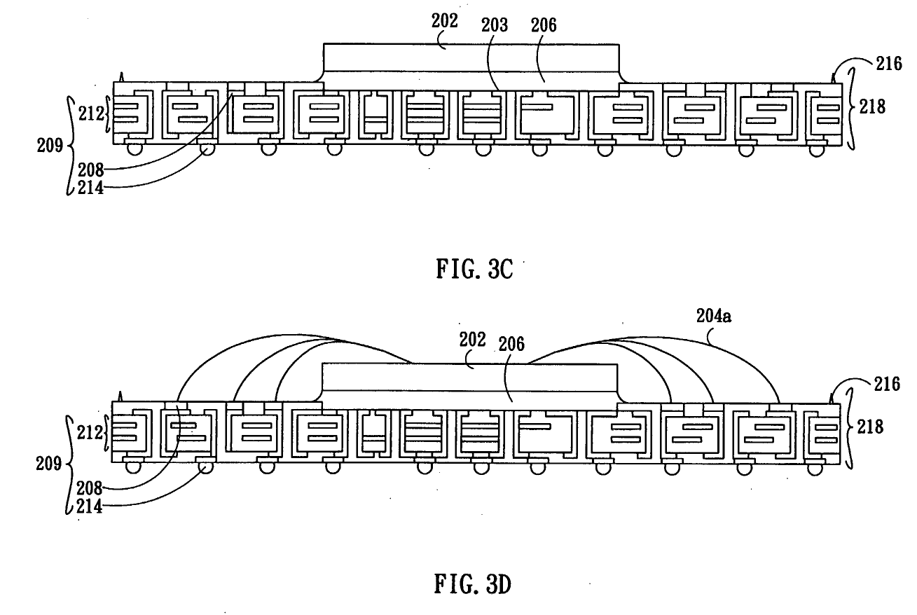

A plurality of wire bonds are formed to electrically connect the pads of the die 202 (not showed in FIG. 3) with the conductive structure of the substrate 218 for the signal transmitting. Copper conductive wires, which are covered by an isolating material, are used in the wire bonding process instead of the gold wires. In this embodiment of the present invention, the isolating material covering the copper conductive wires is copper oxide, but not limit. The surfaces of the copper conductive wires 204 are oxidize or oxidize with high temperature to form the copper oxide layer. The thickness of the copper oxide layers on the surfaces of the copper conductive wires 204 are controlled by the temperature and time of the oxidizing process. However, in the other embodiment of the present invention, the copper oxide layers could be formed to cover the surface of the conductive wires by sputtering or coating.

Furthermore, an insulating layer 210 (or barrier layer) could be formed on the die 202 and the substrate 218 for isolating. The connection regions between the copper conductive wires 204 and the die 202 and the connection regions between the copper conductive wires 204 and the conductive structure 209 are covered by the insulating layer 210. The insulating layer 210 can protect these connection regions from the electrical interrupt. In addition, a stop element 216 is formed on the substrate 218 to confine the formation of the insulating layer 210. The distributing region of the insulating layer can be defined and limited because of the stop element 216 before it solidifies. In the present embodiment, the stop element 216 is an insulated frame with protruding structure but not limit. However, Stop element 216 could be a concave structure, or the insulating layer 210 could be formed without any stop element 216.

As the packaging structure showed in FIG. 2, after the packaging structure of the present invention is accomplished, the packaging structure is covered with the molding compound 222. It can prevent the substrate 212, the die 202 and the copper conductive wires from damage. Then the molding compound 222 is covered by a covered structure 224. In the other embodiment, the covered structure 224c is not necessary when the molding compound is form directly to protect the packaging structure.

Referring the FIG. 3A to 3E illustrate a method for forming the foregoing packaging structure in accordance with one embodiment of the present invention. Firstly in FIG. 3A, a substrate 218 having at least one conductive structure 209 is provided. The conductive structure 209 comprises a first conductive structure 208, second conductive structure 214 and the inner circuits 212 which is used to connect the first conductive structure 208 with the second conductive structure 214. A plurality of the first conducive structures 209 are disposed on the top side of the substrate 218, and A plurality of the second conductive structures 214 are disposed on the back side of the substrate 218.

Referring to FIG. 3B, a die-attach material 206 is smeared on the substrate 218. The die 202 is fastened on the substrate 218 by the die-attach material 206. There are many methods to smear the die-attach material 206 on the substrate 218 and all of them can be used in the present invention. One of the methods to smear the die-attach material 206 is dispensing. And referring to FIG. 3C, the die 202 is fastened on the substrate 218 by the die-attach material 206, which has been smeared on the substrate 218 in prior process. In the embodiment of the present invention, the curing process or baking process is needed to use to solidify the die-attach material 206, so a solidifying process is necessary, but not limit. In other embodiment, the die-attach material 206 is the material which can be solidified by itself at room temperature, or another material which can be used to fastened the die 202 without any solidifying process. Therefore, the solidifying process including the curing process (or baking process) and cooling process is not necessary in those embodiment.

Referring to FIG. 3D, a plurality of the copper conductive wires 204a are formed to connect the die 202 and the first conductive structure 208 of the conductive structure 209. The signal is transmitted by the electrical connection between the copper conductive wires 204a, the die 202, the substrate 218, and the external circuits (not showed in FIG. 3D). Then referring to FIG. 3E, an insulating layer 210 is formed on the die 202 and the substrate 218. The insulating layer 210 can be only formed on the regions which is necessary to be electrically isolated, such as the connecting region of the copper conductive wires 204a and the conductive structure 209. Or like this embodiment of the present invention, an isolating material is formed on the most part of the surface of the die 202 and the substrate 218. The isolating material can be liquid state or colloid state. After curing process or baking process, the isolating material is solidified to form the insulating layer 210. The connection regions between the die 202 and the copper conductive wires are cover by the insulating layer 210. And the connection regions between the substrate 218 and the copper conductive wires are cover by the insulating layer 210, too. Therefore, the passing ways of the electric current are electrical insulated from each other, and the short, which is caused by the exposing metal of these connection region. Besides, before the insulating layer 210 is formed, the stop element 216 is formed to the outside of the region, which is prepared to form the insulating layer 210. Therefore, the distributing region of the insulating layer can be defined and restricted in the desired region.

When the isolating material is solidified to form the insulating layer 210 by the curing process, a copper oxide layer is formed on the surface of the copper conductive wire 204a by the high temperature of the curing process simultaneously. And the surface of the copper conductive wire 204a is covered by the copper oxide layer to form the isolating layer which surrounded the copper conductive wires 204. The thickness of the copper oxide layer on the surface of the copper conductive wires is controlled by the process time and the temperature of the oxidizing process.

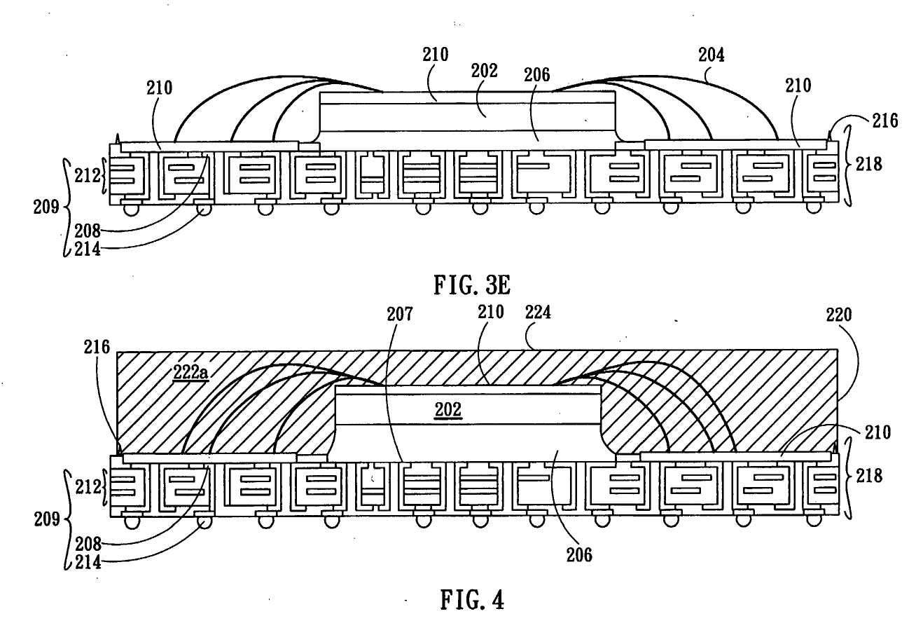

Referring to FIG. 4, in the packing structure of the present invention, the conductively filled material 222a, such as silver epoxy, is used instead of the molding compound 222. The substrate 218, the die 202 and the copper conductive wires 204 covered by the copper oxide are covered by the conductively filled material 222a. The conductively filled material 222a is connected with the die-attach material 206 and the ground openings 207 to form an electrical ground net of the substrate 218 to provide a shield in order to protect the package from the electrical interference and the magnetic interference. An isolated structure 220, such as wall frame configuration, can be used to define and to limit the distributed region of the conductively filled material 222a. Then, a covered structure 224, such as thermally conductive cover, is disposed above the isolated structure 220.

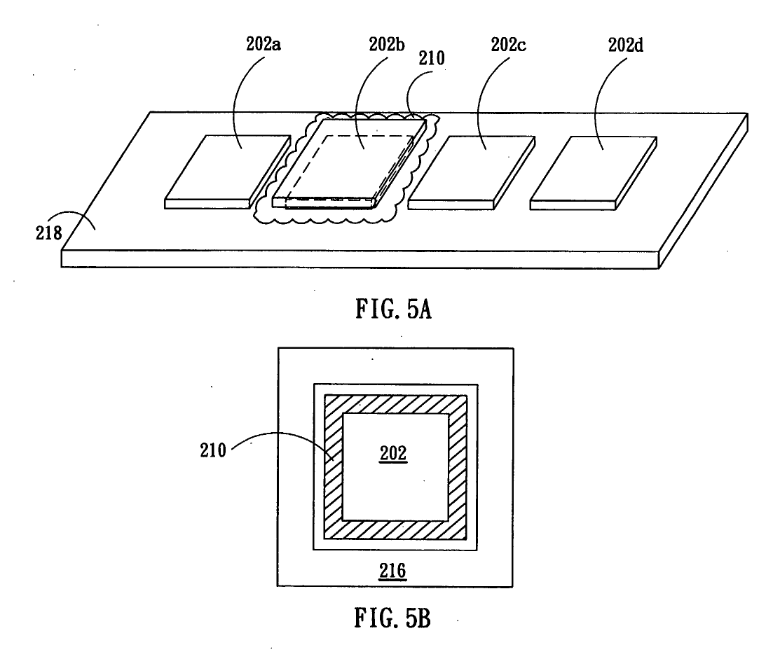

In the present invention, there are many methods to limit the distributing region of the insulating layer 210, and the method, in which the protruding structure or the concave structure is used as the insulating layer 210, but it is not the only way. Referring to FIG. 5A, a plurality of dies 202a, 202b, 202c and 202d are attached to the substrate 218 and they are packaged in a single packaging structure. The formation of the insulating layer 210 could be either confined or not confined as in this example. As showed in FIG. 5A, there is no any stop element on the substrate 218 and the formation of insulating layer 210 is not confined and can be formed on any region of the substrate 218.

The stop element 216 used in the packaging structure of the present invention can be a wall frame configuration encircling whole die 202, as disclosed in previous embodiment, or it can be any shapes by the need. Referring to FIG. 5B, in top view of the packaging structure, the isolating materials are filled between the die 202 and the stop element 216 and formed the insulating layer 210 on all regions which is necessary to be protected, such as the top side of the die 202 or the surrounding of the die 202. The stop element 216 can be removed after the insulating layer 210 is formed. Furthermore, the stop element 216 can be used as the isolated structure to define the distributed region of the conductively filled materials.

The foregoing description is not intended to be exhaustive or to limit the invention to the precise forms disclosed. Obvious modifications or variations are possible in light of the above teachings. In this regards, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly and legally entitled.

What is claimed is:

1. A packaging structure, comprising:
a substrate having at least one conductive structure;
a die fastened on said substrate; and
a plurality of copper conductive wires, wherein an isolating material is formed on a surface of each said copper conductive wires and said copper conductive wires are electrically connected between said die and said conductive structure.

2. The packaging structure of claim 1, wherein said isolating material is a copper oxide layer.

3. The packaging structure of claim 2, wherein said copper oxide layer is formed by oxidizing the surface of said copper conductive wires.

4. The packaging structure of claim 2, wherein said copper oxide layer is formed by oxidizing the surface of said copper conductive wires at high temperature.

5. The packaging structure of claim 2, wherein said copper oxide layer is formed by sputtering copper oxide on the surface of said copper conductive wires.

6. The packaging structure of claim 2, wherein said copper oxide layer is formed by coating copper oxide on the surface of said copper conductive wires.

7. The packaging structure of claim 1, further comprising a conductively filled material fastened between said copper conductive wires.

8. The packaging structure of claim 7, further comprising a ground structure electrically connected with said conductively filled material.

9. The packaging structure of claim 8, further comprising a ground opening and said ground structure is formed on said ground opening.

10. The packaging structure of claim 1, further comprising a insulating layer which covers connection regions of said copper conductive wires and said conductive structure.

11. The packaging structure of claim 1, further comprising a insulating layer which covers connection regions of said copper conductive wires and said die.

12. The packaging structure of claim 1, wherein said conductive structure, comprising:
a first conductive structure which is disposed on one side of said substrate; and
a second conductive structure which is disposed on another side of said substrate.

13. The packaging structure of claim 12, wherein said first conductive structure comprises at least one pad.

14. The packaging structure of claim 12, wherein said second conductive structure comprises a plurality of solder balls.

15. A packaging method, comprising:
providing a substrate, said substrate has at least one conductive structure;
fastening a die on said substrate;
electrically connecting a plurality of copper conductive wires between said die and said conductive structure; and
forming an isolating material to cover surface of said copper conductive wires.

16. The packaging method of claim 15, wherein said forming the isolating material step is to form a copper oxide layer.

17. The packaging method of claim 16, wherein said forming a copper oxide layer step is to oxidize the surface of said copper conductive wires.

18. The packaging method of claim 16, wherein said forming a copper oxide layer step is to sputter copper oxide on the surface of said copper conductive wires.

19. The packaging method of claim 16, wherein said forming a copper oxide layer step is to coat copper oxide on the surface of said copper conductive wires.

20. The packaging method of claim 15, further comprising forming a conductively filled material between said copper conductive wires.

21. The packaging method of claim 20, further comprising forming a ground structure which is electrically connected with said conductively filled material.

22. The packaging method of claim 21, further comprising a ground opening and said ground structure is formed on said ground opening.

23. The packaging method of claim 15, further comprising forming a insulating layer to cover connection regions of said copper conductive wires and said conductive structure.

24. The packaging method of claim 15, further comprising forming a insulating layer to cover connection regions of said copper conductive wires and said die.

25. The packaging method of claim 16, further comprising a curing process

26. The packaging method of claim 25, wherein said forming a copper oxide layer step is to oxidize the surface of said copper conductive wires by said curing process.

27. The packaging structure of claim 15, wherein said forming conductive structure step, comprising:
forming a first conductive structure on one side of said substrate; and
forming a second conductive structure on another side of said substrate, and said first conductive structure is electrically connected said second conductive structure.

28. The packaging method of claim 20, wherein said conductively filled material comprises a conductive silver epoxy.
